(19) United States
(12) Patent Application Publication
(10) Pub. No.: US 2021/0305286 A1
(43) Pub. Date: Sep. 30, 2021

(54) TFT, METHOD FOR MANUFACTURING THE SAME, AND TFT ARRAY

(71) Applicant: CHONGQING KONKA PHOTOELECTRIC TECHNOLOGY RESEARCH INSTITUTE CO., LTD., Chongqing City (CN)

(72) Inventors: Liuzhong LI, Chongqing City (CN); Kaiyi WU, Chongqing City (CN); Ziping LIN, Chongqing City (CN)

(21) Appl. No.: 17/057,919

(22) PCT Filed: Nov. 21, 2019
(86) PCT No.: PCT/CN2019/119807

§ 371 Date: Nov. 23, 2020

(51) Int. Cl. H01L 27/12; H01L 29/786; H01L 29/66

(52) U.S. Cl. CPC H01L 27/1288; H01L 27/1225; H01L 29/66969; H01L 27/1255; H01L 29/78693; H01L 27/124

(57) ABSTRACT

A TFT, a method for manufacturing the same, and a TFT array are provided. The method for manufacturing a TFT includes the following. A gate insulation layer is formed on a gate electrode layer. A MOS layer and an etching protective layer are sequentially deposited on the gate insulation layer. A metal electrode layer is formed on the gate insulation layer and the etching protective layer. The metal electrode layer is etched to obtain a source electrode layer and a drain electrode layer. The etching protective layer is etched to expose the MOS layer.

### RELATED APPLICATION

The present application is a national phase of International Application No. PCT/CN2019/119807, filed Nov. 21, 2019.

### TECHNICAL FIELD

This disclosure relates to the field of semiconductor optoelectronic technology, and more particularly to a thin-film transistor (TFT), a method for manufacturing a TFT, and a TFT array.

### BACKGROUND

With development of display technology, various display devices such as liquid crystal display (LCD) devices, organic electroluminescence display (OLED) devices, or inorganic electroluminescence display (such as mini-LED, or micro-LED) devices are widely used. Each liquid crystal pixel in the LCD device is driven by a thin-film transistor (TFT) integrated behind the pixel, which is possible to display information at a high speed, a high brightness, and a high contrast and is currently one of the most excellent color display devices.

The TFT includes a semiconductor layer. The semiconductor layer has source/drain regions doped with high-concentration dopants, a channel region formed between the source/drain region, a gate disposed corresponding to the channel region and insulated from the semiconductor layer, and a source/drain in contact with each source/drain region. In an existing TFT, a metal oxide semiconductor (MOS) material is often used for a gate electrode channel. The MOS material includes In—Ga oxide, In—Zn oxide, or In-M-Zn oxide (where M can be Al, Ga, Y, La, Ce, Sn, or the like). An amorphous MOS composed of indium, gallium, zinc, and oxygen (that is, In—Ga—Zn—O, and “IGZO” for short) is usually used, and on the MOS of IGZO, source-drain electrodes are formed. When the source-drain electrodes are etched, an etchant will damage the MOS of IGZO, and as a result, the performance of the entire TFT will be adversely affected.

Therefore, the manner in the related art is in a need of improvement.

### SUMMARY

Considering disadvantages of the related art, implementations provide a TFT, a method for manufacturing a TFT, and a TFT array, which can solve a problem that a MOS of IGZO will be damaged by an etchant during etching of source-drain electrodes and thus the performance of the entire TFT will be adversely affected.

In a first aspect, a method for manufacturing a TFT is provided. The method includes the following. A gate insulation layer is formed on a gate electrode layer. A MOS layer and an etching protective layer are sequentially deposited on the gate insulation layer. A metal electrode layer is formed on the gate insulation layer and the etching protective layer. The metal electrode layer is etched to obtain a source electrode layer and a drain electrode layer. The etching protective layer is etched to expose the MOS layer.

In some implementations, the metal electrode layer is etched to obtain the source electrode layer and the drain electrode layer as follows. A photoresist material layer is formed on the metal electrode layer, and the photoresist material layer is patterned to obtain a photoresist layer. The metal electrode layer is etched, and a pattern of the photoresist layer is transferred onto the metal electrode layer to obtain the source electrode layer and the drain electrode layer.

In some implementations, the photoresist material layer is formed on the metal electrode layer, and the photoresist material layer is patterned to obtain the photoresist layer as follows. The photoresist material layer is formed on the metal electrode layer. The photoresist material layer is exposed and developed and a part of the photoresist material layer is removed to obtain the photoresist layer, where the part of the photoresist material layer removed is on a portion of the metal electrode layer in contact with the etching protective layer.

In some implementations, the method further includes the following after the metal electrode layer is etched to obtain the source electrode layer and the drain electrode layer. The photoresist layer on the metal electrode layer is removed. An indium tin oxide (ITO) layer is formed on the source electrode layer, the drain electrode layer, and a gate electrode channel.

In some implementations, the method further includes the following after the ITO layer is formed on the source electrode layer, the drain electrode layer, and the gate electrode channel. A photoresist material layer is formed on the ITO layer, and the photoresist material layer is patterned to obtain a photoresist layer. The ITO layer is etched, and a pattern of the photoresist layer is transferred onto the ITO layer.

In some implementations, the method further includes the following after the etching protective layer is etched to expose the MOS layer. A protective layer is formed on the source electrode layer, the drain electrode layer, and a gate electrode channel.

In some implementations, the etching protective layer is a titanium metal layer, and the etching protective layer has a thickness of 150˜250 Å.

In some implementations, the metal electrode layer has a double-layered metal structure including an aluminum metal layer and a molybdenum metal layer, where the aluminum metal layer has a thickness of 2500˜3000 Å, and the molybdenum metal layer has a thickness of 300˜500 Å.

In a second aspect, a TFT is provided. The TFT includes a gate electrode layer, a gate insulation layer disposed on the gate electrode layer, a MOS layer disposed on the gate insulation layer, an etching protective layer disposed on the MOS layer, and a source electrode layer and a drain electrode layer disposed on the gate insulation layer and spaced apart at two ends of the etching protective layer.

In some implementations, the etching protective layer is disposed on a surface of the MOS layer away from the gate electrode layer, and the etching protective layer, before being etched, completely covers the MOS layer.

In some implementations, the TFT further includes an ITO layer. The ITO layer is disposed on the drain electrode layer and the gate insulation layer.

In some implementations, the TFT further includes a protective layer. The protective layer is disposed on the source electrode layer, the drain electrode layer, the MOS layer, and the ITO layer.

In some implementations, the protective layer is made of an organic material, and the protective layer has a thickness of 2˜4 μm.

In a third aspect, a TFT array is provided. The TFT array includes at least the TFT described in the second aspect.

In some implementations, the TFT array further includes a storage capacitor, a metal overlap region, and a substrate contact hole.

Advantageous effects: Implementations provide a TFT, a method for manufacturing the same, and a TFT array. By forming the etching protective layer on the MOS layer, the MOS layer can be protected by the etching protective layer during etching of the metal electrode layer and the ITO layer, which can avoid etching the MOS layer by an etchant and thus affecting the performance of the TFT. On the other hand, there is no need to add an extra protective layer for protecting the MOS layer, which is simple in manufacturing process and low in cost.

### BRIEF DESCRIPTION OF THE DRAWINGS

FIG. 1 is a flowchart of a method for manufacturing a TFT according to implementations.

FIG. 2 is a schematic diagram illustrating a process of manufacturing a TFT according to implementations.

FIG. 3 is a schematic structural diagram of a TFT according to implementations.

FIG. 4 is a schematic structural diagram of a TFT array according to implementations.

FIG. 5 is a schematic diagram illustrating a process of manufacturing a TFT array according to implementations.

### DETAILED DESCRIPTION

In order for clarity and better understanding of purposes, technical solutions, and advantages of implementations, implementations will be hereinafter described in further detail with reference to the accompanying drawings. It should be understood that, implementations described herein are intended for explaining, rather than limiting, the disclosure.

In the related art, an etchant will destroy a MOS layer during etching of a source electrode layer and a drain electrode layer, and as a result, the performance of the entire TFT will be affected. Therefore, in order to solve the above problem, implementations provide a method for manufacturing a TFT.

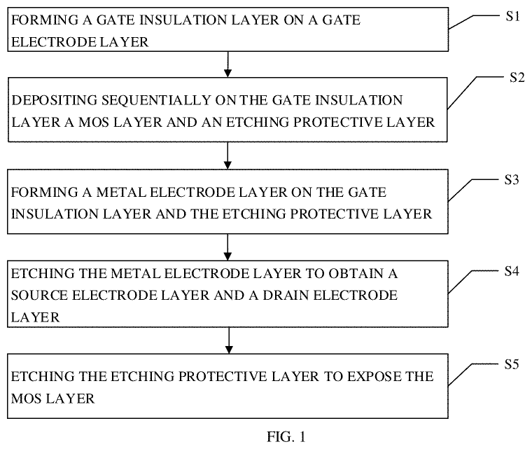

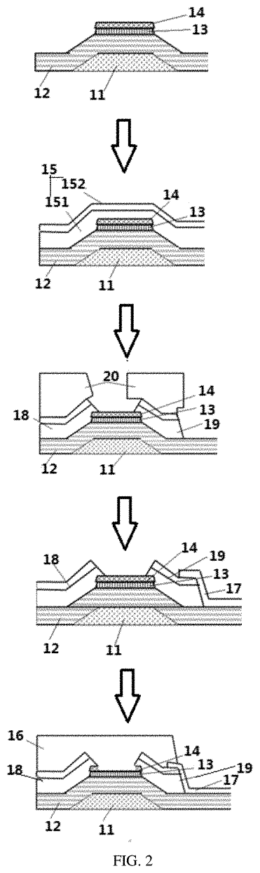

FIG. 1 is a flowchart of a method for manufacturing a TFT according to implementations. FIG. 2 is a schematic diagram illustrating a process of manufacturing a TFT according to implementations. As illustrated in FIG. 1 and FIG. 2, the method includes the following.

At block S1, a gate insulation layer 12 is formed on a gate electrode layer 11.

In order to manufacture the TFT, it is necessary to first select a material used for the gate electrode layer 11 of the TFT. The gate electrode layer 11 may be made of a metal material (such as copper, aluminum, tungsten, gold, silver, etc.) or may be a conductive semiconductor material (such as doped polysilicon). Then the gate insulation layer 12 is formed on the gate electrode layer 11. The gate insulation layer 12 is mainly made of an inorganic material, for example, an oxide material such as silica or a nitride material such as silicon nitride. The gate insulation layer 12 may be formed on the gate electrode layer 11 through deposition or coating, for example, physical vapor deposition (PVD), chemical vapor deposition (CVD), or coating with a coater. As an example, the gate insulation layer 12 may be formed on the gate electrode layer 11 through plasma CVD (PCVD).

As illustrated in FIG. 1 and FIG. 2, the method further includes the following.

At block S2, a metal-oxide semiconductor (MOS) layer 13 and an etching protective layer 14 are sequentially deposited on the gate insulation layer 12.

In an example, after the gate insulation layer 12 is formed on the gate electrode layer 11, the MOS layer 13 and the etching protective layer 14 are sequentially deposited on the gate insulation layer 12, where the etching protective layer 14 completely covers the MOS layer 13 to protect the MOS layer 13 from being etched by an etchant while source/drain electrodes are being formed. The MOS layer 13 may be made of a metal oxide such as In—Ga oxide, In—Zn oxide, or In-M-Zn oxide, where M is one of Al, Ga, Y, La, etc., or may be made of a compound semiconductor such as SiGe, GaAs, etc. As an example, the MOS layer 13 may be made of an amorphous MOS composed of indium, gallium, zinc, aluminum, tin, and oxygen (that is, In—Ga—Zn—O, and “IGZO” for short). An IGZO film has a thickness of 300˜500 Å (Ångström).

It is necessary to etch to obtain a gate electrode channel on the MOS layer 13, and an etchant used in wet etching (such as mixed acid of nitric acid, phosphoric acid, and acetic acid, or oxalic acid), or dry etching (such as plasma etching using Cl₂) can etch the MOS layer 13. Therefore, in order not to affect the MOS layer 13 during etching, according to implementations, the etching protective layer 14 is deposited on the MOS layer 13. The etching protective layer 14 may be any metal layer that cannot be etched by an etchant, such as titanium, tungsten, molybdenum tungsten alloy, or the like. In some examples, the etching protective layer 14 is a titanium metal layer considering that: when used as a protective layer during etching for the gate electrode channel, the titanium metal layer can protect the MOS layer 13, and on the other hand, the gate electrode channel thus obtained is easy to control. In addition, a thinner etching protective layer 14 for protecting the MOS layer 13 is usually more desirable, but if the etching protective layer 14 is made too thin, it is not beneficial to protecting the MOS layer 13 during etching. Therefore, according to implementations, the etching protective layer 14 is controlled to be 150˜250 Å in thickness. As an example, the etching protective layer 14 has a thickness of 250 Å.

As illustrated in FIG. 1 and FIG. 2, the method further includes the following.

At block S3, a metal electrode layer 15 is formed on the gate insulation layer 12 and the etching protective layer 14.

According to implementations, after the MOS layer 13 and the etching protective layer 14 are sequentially deposited on the gate insulation layer 12, the metal electrode layer 15 is formed on the gate insulation layer 12 and the etching protective layer 14, where the metal electrode layer 15 completely covers the etching protective layer 14 and the gate insulation layer 12. The metal electrode layer 15 has a double-layered metal structure including a first metal layer 151 and a second metal layer 152. In some implementations, the first metal layer 151 is an aluminum metal layer and the second metal layer 152 is a molybdenum metal layer. The aluminum metal layer, as a main circuit wire of the TFT, is in direct contact with the etching protective layer 14. On the other hand, aluminum is low in resistance, and is beneficial to manufacturing the TFT without causing pollution. In addition, the first metal layer 151, as the main circuit wire of the TFT, is thicker than the second metal layer 152. The first metal layer 151 has a thickness of 2500˜3000 Å. The second metal layer 152 has a thickness of 300˜500 Å. The metal electrode layer 15 can be formed on the etching protective layer 14 and the gate insulation layer 12 through etching, coating, sputtering, etc. As an example, the metal electrode layer 15 can be formed on the etching protective layer 14 and the gate insulation layer 12 through sputtering.

As illustrated in FIG. 1 and FIG. 2, the method further includes the following.

At block S4, the metal electrode layer 15 is etched to obtain a source electrode layer 18 and a drain electrode layer 19.

After the metal electrode layer 15 is formed on the gate insulation layer 12 and the etching protective layer 14, since the MOS layer 13 is protected by the etching protective layer 14, the metal electrode layer 15 can be directly etched by an etchant. During etching, it is only necessary to remove a portion of the metal electrode layer 15 that is in contact with the MOS layer 13 (that is, the portion that is in contact with the etching protective layer 14), and the remaining portion of the metal electrode layer 15 at two ends of the etching protective layer 14 is retained, thus obtaining the source electrode layer 18 and the drain electrode layer 19.

The manner of etching can include wet etching and dry etching. According to implementations herein, the metal electrode layer 15 is etched by an etchant, that is, through wet etching. As an example, the etchant may be a mixed acid solution of nitric acid, phosphoric acid, and acetic acid. Since titanium will not be etched by the etchant, the MOS layer 13 under the etching protective layer 14 can be protected. By etching the metal electrode layer 15 with aid of the mixed acid solution, the source electrode layer 18 and the drain electrode layer 19 that have an ideal vertical width can be obtained.

In some implementations, operations at block S4 include the following.

At block S41, a photoresist material layer is formed on the metal electrode layer, and the photoresist material layer is patterned to obtain a photoresist layer.

At block S42, the metal electrode layer is etched, and a pattern of the photoresist layer is transferred onto the metal electrode layer to obtain the source electrode layer and the drain electrode layer.

In some implementations, after the metal electrode layer 15 is formed on the gate insulation layer 12 and the etching protective layer 14, the photoresist material layer is formed on the metal electrode layer 15, and the photoresist material layer is patterned to obtain the photoresist layer 20, where the photoresist material layer is made of a material that will not be etched by an etchant. After the photoresist material layer is patterned to obtain the photoresist layer 20, the metal electrode layer 15 is etched. The etchant will only etch a portion of the metal electrode layer 15 that is not covered by photoresist layer 20, and the remaining portion of the metal electrode layer 15 that is covered by the photoresist layer 20 will not be etched due to protection by the photoresist layer 20. As such, the pattern of the photoresist layer 20 is transferred onto the metal electrode layer 15, thereby obtaining the source electrode layer 18 and the drain electrode layer 19.

In some implementations, operations at block S41 include the following.

At block S411, the photoresist material layer is formed on the metal electrode layer.

At block S412, the photoresist material layer is exposed and developed and a part of the photoresist material layer is removed to obtain the photoresist layer, where the part of the photoresist material layer removed is on a portion of the metal electrode layer in contact with the etching protective layer.

As an example, the photoresist material layer is first formed on the metal electrode layer 15 through coating. Then the photoresist material layer undergoes mask exposure and development with aid of an exposure machine, and the part of the photoresist material layer, which is on the portion of the metal electrode layer 15 in contact with the etching protective layer 14, is removed to obtain the photoresist layer 20. In other words, after the photoresist material layer is patterned, the portion of the metal electrode layer 15 in contact with the etching protective layer 14 has no photoresist layer 20, and the remaining portion of the metal electrode layer 15 at two ends of the etching protective layer 14 is protected by the photoresist layer 20. During a subsequent etching of the metal electrode layer 15, the portion of the metal electrode layer 15 in direct contact with the etching protective layer 14 will be directly etched due to absence of protection by the photoresist layer 20, and the remaining portion of the metal electrode layer 15 at two ends of the etching protective layer 14 will not be etched due to protection by the photoresist layer 20. As such, the source electrode layer 18 and the drain electrode layer 19 can be obtained at two ends of the etching protective layer 14 respectively. As an example, the photoresist layer 20 has a thickness of 1.5˜2 μm (micrometer).

In some implementations, after operations at block S412, the following can be conducted.

At block S413, the photoresist layer on the metal electrode layer 15 is removed.

At block S414, an indium tin oxide (ITO) layer 17 is formed on the source electrode layer 18, the drain electrode layer 19, and the gate electrode channel.

Since the TFT needs to be coupled with other components (such as a storage capacitor, a pixel capacitor, etc.) to cooperatively drive a liquid crystal pixel, the ITO layer 17 is formed on the source electrode layer 18, the drain electrode layer 19, and the gate electrode channel after the source electrode layer 18 and the drain electrode layer 19 are formed at two ends of the MOS layer 13, and via the ITO layer 17, the TFT is coupled with the storage capacitor. As mentioned in the foregoing operations, the photoresist layer 20 is coated on the metal electrode layer 15 before the metal electrode layer 15 is etched to obtain the source electrode layer 18 and the drain electrode layer 19. Therefore, before the ITO layer 17 is formed, the photoresist layer 20 on the metal electrode layer 15 needs to be removed with aid of a photoresist stripper. Then the ITO layer 17 is formed on the source electrode layer 18, the drain electrode layer 19, and the gate electrode channel.

In some implementations, after operations at block S414 are performed, the following can be conducted.

At block S415, a photoresist material layer is formed on the ITO layer 17, and the photoresist material layer is patterned to obtain a photoresist layer 20.

At block S416, the ITO layer 17 is etched, and a pattern of the photoresist layer 20 is transferred onto the ITO layer 17.

As an example, in order to avoid short circuit between the source electrode layer 18, the drain electrode layer 19, and the gate electrode channel, after the ITO layer 17 is formed on the source electrode layer 18, the drain electrode layer 19, and the gate electrode channel, it is necessary to etch with the etchant an unnecessary portion of the ITO layer 17. In order to remove the unnecessary portion of the ITO layer 17, a manner that is similar to the foregoing operations of etching the metal electrode layer 15 is adopted. The photoresist material layer is first formed on the ITO layer 17, and the photoresist material layer is exposed and developed to pattern the photoresist material layer, thereby obtaining the photoresist layer. Then the ITO layer 17 is etched, such that a portion of the ITO layer 17 that has the photoresist layer is retained and the remaining portion of the ITO layer 17 that has no photoresist layer for protection is removed, and in this way, a necessary portion of the ITO layer 17 can be retained.

As an example, the ITO layer 17 is etched through wet etching. For example, the etchant is oxalic acid. Although oxalic acid can also etch the MOS layer 13, the MOS layer 13 is still completely covered by the etching protective layer 14 in this situation, and the etching protective layer 14 cannot be etched by oxalic acid. Therefore, in addition to protecting the MOS layer 13 during etching of the metal electrode layer 15, the etching protective layer 14 can protect the MOS layer 13 during etching of the ITO layer 17.

As illustrated in FIG. 1 and FIG. 2, the method further includes the following.

At block S5, the etching protective layer 14 is etched to expose the MOS layer 13.

In some implementations, the etching protective layer 14 is used for protecting the MOS layer 13 from being etched. After etching of the metal electrode layer 15 and etching of the ITO layer 17 are completed, in order to define the gate electrode channel between the source electrode layer 18 and the drain electrode layer 19, the etching protective layer 14 needs to be removed to expose the MOS layer 13.

As previously mentioned, the manner of etching can include wet etching and dry etching. According to implementations, the etching protective layer 14 is removed through dry etching to expose the MOS layer 13. Therefore, in addition to inability to be etched by the etchant, the etching protective layer 14 of implementations is required to be able to be etched through dry etching. As an example, plasma etching using BCl₃/Cl₂ is performed on the etching protective layer 14 to expose the MOS layer 13 mainly because the titanium metal layer is easily etched by BCl₃/Cl₂ but BCl₃/Cl₂ will not etch the molybdenum metal layer and the aluminum metal layer of the source electrode layer 18 and the drain electrode layer 19. In such a process, although BCl₃/Cl₂ plasma can also etch the MOS layer 13, the MOS layer 13 is completely covered by the etching protective layer 14 and therefore, the MOS layer 13 can be etched only after the etching protective layer 14 is completely etched. By controlling a duration of etching, the MOS layer 13 can be controlled to be etched only by not more than 100 Å after etching of the etching protective layer 14 is completed. As previously mentioned, the MOS layer 13 has a thickness of 300˜500 Å. Even though etched by 100 Å, the MOS layer still has a thickness of 200˜400 Å.

As illustrated in FIG. 1 and FIG. 2, the method further includes the following.

At block S6, a protective layer is formed on the source electrode layer 18, the drain electrode layer 19, and the gate electrode channel.

In some implementations, after the etching protective layer 14 is etched to expose the MOS layer 13, it is necessary to form the protective layer 16 on the source electrode layer 18, the drain electrode layer 19, and the gate electrode channel. The protective layer 16 can, on one hand, protect the source electrode layer 18, the drain electrode layer 19, and the gate electrode channel and on the other hand, position the TFT. The protective layer 16 is made of an organic material and has a thickness of 2˜4 μm. The protective layer 16 can be formed though photoresist coating, exposure, and development.

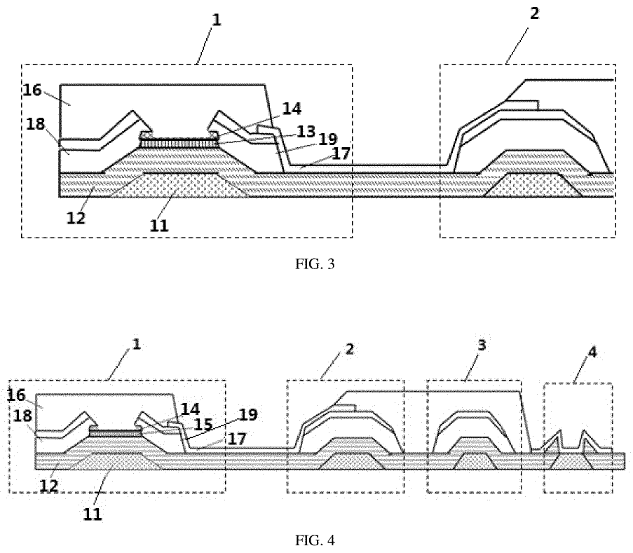

Implementations further provide a TFT. The TFT is manufactured with the method described in the foregoing implementations. FIG. 3 is a schematic structural diagram of a TFT according to implementations. The TFT 1 includes a gate electrode layer 11, a gate insulation layer 12, a MOS layer 13, an etching protective layer 14, a source electrode layer 18, a drain electrode layer 19, an ITO layer 17, and a protective layer 16.

The gate electrode layer 11 is completely covered by the gate insulation layer 12. The MOS layer 13 is on a surface of the gate insulation layer 12 away from the gate electrode layer 11, and an orthographic projection of the gate insulation layer 12 on the gate electrode layer 11 falls on the gate electrode layer 11. The etching protective layer 14 is on a surface of the MOS layer 13 away from the gate electrode layer 11. The etching protective layer 14 completely covers the MOS layer 13 before being etched, and an orthographic projection of the etching protective layer 14 on the gate electrode layer 11 coincides with that of the MOS layer 13 on the gate electrode layer 11. The source electrode layer 18 and the drain electrode layer 19 are on a surface of the gate insulation layer 12 away from the gate electrode layer 11, and are located respectively at both ends of the MOS layer 13 as well as both ends of the etching protective layer 14. A gate electrode channel is defined between the source electrode layer 18 and the drain electrode layer 19 by etching a metal electrode layer 15. The TFT 1 further includes the ITO layer 17. The ITO layer 17 is configured to be coupled with a storage capacitor 2. During actual implementation, when a voltage is applied to the gate electrode layer 11, a gate voltage generates an electric field on the gate insulation layer 12. A power line is directed to a surface of the MOS layer 13 from the gate electrode layer 11, and electric charges are generated on the surface of the MOS layer 13. As the gate voltage increases, the MOS layer 13 may be converted from a depletion layer into an electron accumulation layer, to form an inversion layer. When a strong inversion mode is reached, there will be carriers passing through the gate electrode channel between the source electrode layer 18 and the drain electrode layer 19 under action of a voltage. A source-drain voltage increases until a turn-on voltage is reached, thereby driving a pixel in an LCD.

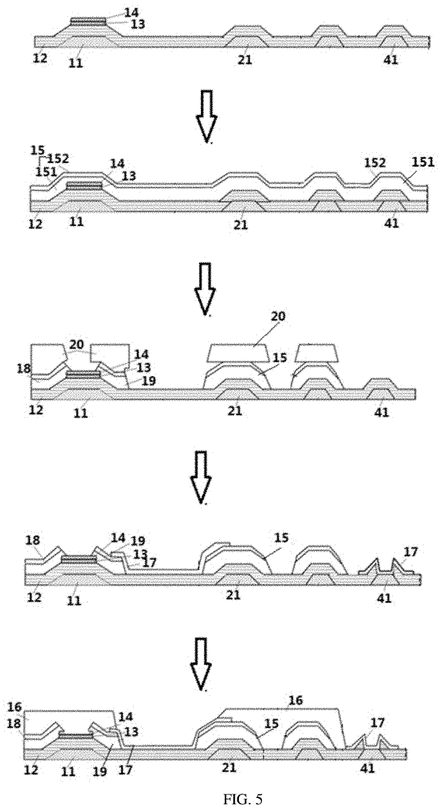

Implementations further provide a TFT array. FIG. 4 is a schematic structural diagram of a TFT array according to implementations. FIG. 5 is a schematic diagram illustrating a process of manufacturing a TFT array according to implementations. Besides the TFT 1 described above, the TFT array further includes a storage capacitor 2, a metal overlap region 3, and a substrate contact hole 4.

The TFT 1 has the same structure as the TFT described in the foregoing implementations, which has been elaborated above. The storage capacitor 2 includes a second gate insulation layer 21, the gate insulation layer 12, the metal electrode layer 15, the ITO layer 17, and the protective layer 16. The gate insulation layer 12 completely covers the second gate insulation layer 21. The metal electrode layer 15 is disposed on a surface of the gate insulation layer 12 away from the second gate insulation layer 21. The ITO layer 17 is disposed on a surface of the metal electrode layer 15 away from the gate insulation layer 12. The ITO layer 17 is coupled with the TFT 1. The protective layer 16 is disposed on a surface of the ITO layer 17 away from the metal electrode layer 15. The protective layer 16 is used for protecting and positioning the storage capacitor 2. A method for manufacturing the storage capacitor 2 corresponds to the method for manufacturing the TFT 1 described in the foregoing implementations. While the gate insulation layer 12 is formed on the gate electrode layer 11, the gate insulation layer 12 is formed on the second gate insulation layer 21. Then the metal electrode layer 15 is formed on the gate insulation layer 12. The metal electrode layer 15 is patterned, such that a portion of the metal electrode layer 15 in contact with the gate insulation layer 12 on the second gate insulation layer 21 is retained due to protection by a photoresist layer 20. Then the ITO layer 17 is formed on the metal electrode layer 15. The ITO layer 17 is patterned such that a portion of the ITO layer 17, coupled with the TFT 1, on the storage capacitor 2 can be retained. The protective layer 16 is deposited on the ITO layer 17 and the metal electrode layer 15, to form the storage capacitor 2.

In some examples, the substrate contact hole 4 includes a fourth gate insulation layer 41, the gate insulation layer 12, and the ITO layer 17. The gate insulation layer 12 is disposed on the fourth gate insulation layer 41, and a portion of the gate insulation layer 12 in contact with the fourth gate insulation layer 41 is etched to expose the fourth gate insulation layer 41. The ITO layer 17 is disposed on the fourth gate insulation layer 41 and the gate insulation layer 12. A method for manufacturing the substrate contact hole 4 corresponds to the method for manufacturing the TFT 1 described in the foregoing implementations. After the foregoing operations at block S4, the portion of the gate insulation layer 12 in contact with the fourth gate insulation layer 41 is etched to expose the fourth gate insulation layer 41. Then the ITO layer 17 is deposited on the fourth gate insulation layer 41 and the gate insulation layer 12, to be coupled with the storage capacitor 2, thereby forming the substrate contact hole 4.

Implementations provide a TFT, a method for manufacturing the same, and a TFT array. The method for manufacturing a TFT includes the following. The gate insulation layer is formed on the gate electrode layer. The MOS layer and the etching protective layer are sequentially deposited on the gate insulation layer. The metal electrode layer is formed on the gate insulation layer and the etching protective layer. The metal electrode layer is etched to form the source electrode layer and the drain electrode layer. The etching protective layer is etched to expose the MOS layer. By forming the etching protective layer on the MOS layer, the MOS layer can be protected by the etching protective layer while the metal electrode layer and the ITO layer are being etched, which can avoid etching the MOS layer by the etchant and thus affecting the performance of the TFT. On the other hand, there is no need to add an extra protective layer for protecting the MOS layer, which has advantages of simple manufacturing process and low cost.

It is to be understood that the disclosure is not to be limited to the disclosed embodiments. For those of ordinary skill in the art, various modifications and equivalent arrangements can be made according to the foregoing implementations, and all the various modifications and equivalent arrangements shall fall within the protection scope of the appended claims.

1. A method for manufacturing a thin-film transistor (TFT), comprising:
forming a gate insulation layer on a gate electrode layer;
depositing sequentially on the gate insulation layer a metal-oxide semiconductor (MOS) layer and an etching protective layer;
forming a metal electrode layer on the gate insulation layer and the etching protective layer;
etching the metal electrode layer to obtain a source electrode layer and a drain electrode layer; and
etching the etching protective layer to expose the MOS layer.

2. The method of claim 1, wherein etching the metal electrode layer to obtain the source electrode layer and the drain electrode layer comprises:
forming a photoresist material layer on the metal electrode layer, and patterning the photoresist material layer to obtain a photoresist layer; and
etching the metal electrode layer, and transferring a pattern of the photoresist layer onto the metal electrode layer to obtain the source electrode layer and the drain electrode layer.

3. The method of claim 2, wherein forming the photoresist material layer on the metal electrode layer, and patterning the photoresist material layer to obtain the photoresist layer comprises:
forming the photoresist material layer on the metal electrode layer; and
exposing and developing the photoresist material layer and removing a part of the photoresist material layer to obtain the photoresist layer, wherein the part of the photoresist material layer removed is on a portion of the metal electrode layer in contact with the etching protective layer.

4. The method of claim 3, further comprising:
after etching the metal electrode layer to obtain the source electrode layer and the drain electrode layer,
removing the photoresist layer on the metal electrode layer; and
forming an indium tin oxide (ITO) layer on the source electrode layer, the drain electrode layer, and a gate electrode channel.

5. The method of claim 4, further comprising:
after forming the ITO layer on the source electrode layer, the drain electrode layer, and the gate electrode channel,
forming a photoresist material layer on the ITO layer, and patterning the photoresist material layer to obtain a photoresist layer; and
etching the ITO layer, and transferring a pattern of the photoresist layer onto the ITO layer.

6. The method of claim 1, further comprising:
after etching the etching protective layer to expose the MOS layer,
forming a protective layer on the source electrode layer, the drain electrode layer, and a gate electrode channel.

7. The method of claim 6, wherein the etching protective layer is a titanium metal layer, and the etching protective layer has a thickness of 150˜250 Å.

8. The method of claim 6, wherein the metal electrode layer has a double-layered metal structure comprising an aluminum metal layer and a molybdenum metal layer, wherein the aluminum metal layer has a thickness of 2500˜3000 Å, and the molybdenum metal layer has a thickness of 300˜500 Å.

9. A TFT, comprising:
a gate electrode layer;
a gate insulation layer disposed on the gate electrode layer;
a MOS layer disposed on the gate insulation layer;
an etching protective layer disposed on the MOS layer; and
a source electrode layer and a drain electrode layer disposed on the gate insulation layer and spaced apart at two ends of the etching protective layer.

10. The TFT of claim 9, wherein the etching protective layer is disposed on a surface of the MOS layer away from the gate electrode layer, and the etching protective layer, before being etched, completely covers the MOS layer.

11. The TFT of claim 9, further comprising an ITO layer disposed on the drain electrode layer and the gate insulation layer.

12. The TFT of claim 11, further comprising a protective layer disposed on the source electrode layer, the drain electrode layer, the MOS layer, and the ITO layer.

13. The TFT of claim 12, wherein the protective layer is made of an organic material, and the protective layer has a thickness of 2˜4 μm.

14. A TFT array comprising at least a TFT, the TFT comprising:
a gate electrode layer;
a gate insulation layer disposed on the gate electrode layer;
a MOS layer disposed on the gate insulation layer;
an etching protective layer disposed on the MOS layer; and
a source electrode layer and a drain electrode layer disposed on the gate insulation layer and spaced apart at two ends of the etching protective layer.

15. The TFT array of claim 14, further comprising a storage capacitor, a metal overlap region, and a substrate contact hole.

16. The TFT array of claim 14, wherein the etching protective layer is disposed on a surface of the MOS layer away from the gate electrode layer, and the etching protective layer, before being etched, completely covers the MOS layer.

17. The TFT array of claim 14, wherein the TFT further comprises an ITO layer disposed on the drain electrode layer and the gate insulation layer.

18. The TFT array of claim 17, wherein the TFT further comprises a protective layer disposed on the source electrode layer, the drain electrode layer, the MOS layer, and the ITO layer.

19. The TFT array of claim 18, wherein the protective layer is made of an organic material, and the protective layer has a thickness of 2˜4 μm.
